(19) United States
(12) Patent Application Publication
(10) Pub. No.: US 2025/0294815 A1
(43) Pub. Date: Sep. 18, 2025

(54) NANOSHEET CHANNEL LAYER OF VARYING THICKNESSES

(71) Applicant: International Business Machines Corporation, Armonk, NY (US)

(72) Inventors: Ruilong Xie, Niskayuna, NY (US); Juntao Li, Cohoes, NY (US); Min Gyu Sung, Latham, NY (US); Julien Frougier, Albany, NY (US); Chanro Park, Clifton Park, NY (US)

(21) Appl. No.: 18/608,426

(22) Filed: Mar. 18, 2024

(51) Int. Cl. H01L 29/786; H01L 29/423; H01L 29/66; H01L 29/775

(52) U.S. Cl. CPC H10D 30/6757; H10D 30/014; H10D 30/031; H10D 30/43; H10D 30/6735; H10D 30/6736

(57) ABSTRACT

A semiconductor structure includes a first nanosheet channel layer having a first middle portion and first outer portions, a second nanosheet channel layer disposed over the first nanosheet channel layer, the second nanosheet channel layer having a second middle portion and second outer portions, wherein a first distance between the first middle portion and the second middle portion defines a first region and a second distance between the first outer portions and the second outer portions defines a second region, wherein the second distance is less than the first distance, a gate dielectric layer disposed in the first region and the second region, wherein the gate dielectric layer pinches off the second region, and a conductive gate layer disposed on the gate dielectric layer disposed in the first region.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes a first nanosheet channel layer having a first middle portion and first outer portions, a second nanosheet channel layer disposed over the first nanosheet channel layer, the second nanosheet channel layer having a second middle portion and second outer portions, wherein a first distance between the first middle portion and the second middle portion defines a first region and a second distance between the first outer portions and the second outer portions defines a second region, wherein the second distance is less than the first distance, a gate dielectric layer disposed in the first region and the second region, wherein the gate dielectric layer pinches off the second region, and a conductive gate layer disposed on the gate dielectric layer disposed in the first region.

In another illustrative embodiment, a semiconductor structure includes a first nanosheet device disposed on a substrate containing a plurality of first nanosheet channel layers, wherein each of the plurality of first nanosheet channel layers has a first middle portion and first outer portions, wherein a first distance between the first middle portion of adjacent first nanosheet channel layers defines a first region and a second distance between the first outer portions of adjacent first nanosheet channel layers defines a second region, wherein the second distance is less than the first distance. The semiconductor structure further includes a second nanosheet device adjacent the first nanosheet device, the second nanosheet device containing a plurality of second nanosheet channel layers, wherein each of the plurality of second nanosheet channel layers has a second middle portion and second outer portions, wherein a third distance between the second middle portion of adjacent second nanosheet channel layers defines a third distance and a fourth distance between the second outer portions of adjacent second nanosheet channel layers defines a fourth region, wherein the fourth distance is less than the third distance. The semiconductor structure further includes a first gate dielectric layer disposed in the first region and the second region, wherein the gate dielectric layer pinches off the second region, a second gate dielectric layer disposed in the third region and the fourth region, wherein the second gate dielectric layer pinches off the fourth region, a first conductive gate layer disposed on the first gate dielectric layer disposed in the first region, and a second conductive gate layer disposed on the second gate dielectric layer disposed in the third region.

In yet another illustrative embodiment, an integrated circuit includes one or more semiconductor devices. At least one of the one or more semiconductor devices is a semiconductor device according to one or more of the foregoing illustrative embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a cross-sectional view of a semiconductor structure for use at a first-intermediate fabrication stage, according to an illustrative embodiment.

FIG. 2 is a cross-sectional view of the semiconductor structure for use at a second-intermediate fabrication stage, according to an illustrative embodiment.

FIG. 3 is a cross-sectional view of the semiconductor structure for use at a third- intermediate fabrication stage, according to an illustrative embodiment.

FIG. 4 is a cross-sectional view of the semiconductor structure for use at a fourth-intermediate fabrication stage, according to an illustrative embodiment.

FIG. 5 is a cross-sectional view of the semiconductor structure for use at a fifth-intermediate fabrication stage, according to an illustrative embodiment.

FIG. 6 is a cross-sectional view of the semiconductor structure for use at a sixth-intermediate fabrication stage, according to an illustrative embodiment.

FIG. 7 is a cross-sectional view of the semiconductor structure for use at a seventh-intermediate fabrication stage, according to an illustrative embodiment.

FIG. 8 is a cross-sectional view of the semiconductor structure for use at an eighth-intermediate fabrication stage, according to an illustrative embodiment.

FIG. 9 is a cross-sectional view of the semiconductor structure for use at a ninth-intermediate fabrication stage, according to an illustrative embodiment.

FIG. 10 is a cross-sectional view of the semiconductor structure for use at a tenth-intermediate fabrication stage, according to an illustrative embodiment.

FIG. 11 is a cross-sectional view of the semiconductor structure for use at an eleventh-intermediate fabrication stage, according to an illustrative embodiment.

FIG. 12 is a cross-sectional view of the semiconductor structure for use at a twelfth-intermediate fabrication stage, according to an illustrative embodiment.

FIG. 13 is a cross-sectional view of the semiconductor structure for use at a thirteenth-intermediate fabrication stage, according to an illustrative embodiment.

### DETAILED DESCRIPTION

This disclosure relates generally to semiconductor devices, and more particularly to semiconductor structures having a nanosheet device with nanosheet channel layers of varying thicknesses, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Nanosheet transistors are being pursued as a viable device architecture for scaling CMOS devices beyond 5 nm node. One challenge in fabricating nanosheet transistors is the difficulty in forming a PFET source/drain region between adjacent nanosheet devices, followed by formation of a replacement metal gate between the nanosheet channel layers of each nanosheet stack. For example, in some applications, inner spacers are formed between nanosheet channel layers to separate an epitaxial pFET-type source/drain region from a replacement metal gate with the epitaxial pFET-type source/drain region being in contact with the inner spacers. This, however, results in defects and a loss of strain for the source/drain region such that there is a relatively low pFET performance. In other applications, no inner spacers are formed to retain the stress of the source/drain region. Thus, to separate the epitaxial pFET-type source/drain region from the replacement metal gate, a pFET type buffer layer is formed between the replacement metal gate and the replacement epitaxial pFET-type source/drain region. This, however, results in a relatively high capacitance between the source/drain region and the replacement metal gate while also having a breakdown concern.

Illustrative embodiments overcome the foregoing drawback by providing a nanosheet transistor with nanosheet channel layers having a middle portion of a first thickness and outer portions of a second thickness less than the first thickness. This configuration, in turn, allows for the formation of a replacement metal gate between the nanosheet channel layers in which the middle portion contains a gate dielectric layer and a conductive gate layer and outer portions that contain the gate dielectric layer. Thus, the nanosheet transistor will have a reduced capacitance between the source/drain region and the replacement metal gate while also having no breakdown concern. In addition, the source/drain region can retain its strain.

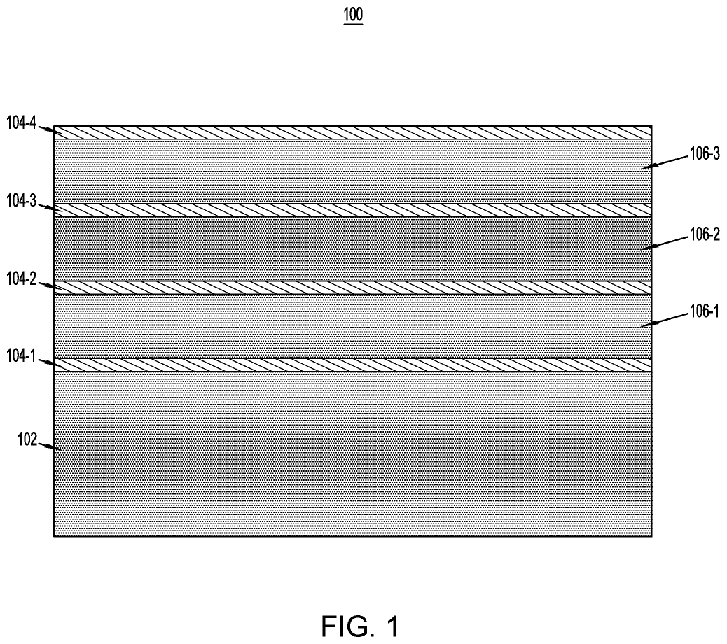

Referring now to the drawings in which like numerals represent the same or similar elements, FIGS. 1-13 illustrate various processes for fabricating a nanosheet transistor with a nanosheet channel layer of different thicknesses. Note that the same reference numeral (100) is used to denote the semiconductor structure through the various intermediate fabrication stages illustrated in FIGS. 1-13. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-13 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIGS. 1-13 show a semiconductor structure 100 in accordance with an illustrative embodiment. Referring now to FIG. 1, semiconductor structure 100 is shown during an intermediate step of a method of fabricating a nanosheet transistor structure according to an embodiment of the invention. Semiconductor structure 100 includes a substrate 102. Substrate 102 may be formed of any suitable semiconductor material, including various silicon-containing materials including but not limited to silicon (Si), silicon germanium (SiGe), and multi-layers thereof. Although silicon is the predominantly used semiconductor material in wafer fabrication, alternative semiconductor materials can be employed as additional layers, such as, but not limited to, SiGe, germanium (Ge), gallium arsenide (GaAs), gallium indium arsenide (InGaAs), cadmium telluride (CdTe), zinc selenide (ZnSe), etc. In one illustrative embodiment, substrate 102 is silicon.

Nanosheets are initially formed over substrate 102, where the nanosheets include sacrificial layers 104-1 to 104-4 (collectively, sacrificial layers 104), and nanosheet channel layers 106-1 to 106-3 (collectively, nanosheet channel layers 106). Sacrificial layers 104 are formed of SiGe. For example, sacrificial layers 104 may have a relatively higher percentage of Ge (e.g., 55% Ge), or may have a relatively lower percentage of Ge (e.g., 25% Ge). In some embodiments, sacrificial layers 104 are formed of a first thickness less than the thickness of nanosheet channel layers 106. In some embodiments, sacrificial layers 104 can be formed of a thickness ranging from about 1 nanometer (nm) to about 5 nm.

Nanosheet channel layers 106 may be formed of Si or another suitable material (e.g., a material similar to that used for the substrate 102). Nanosheet channel layers 106 are formed of a thickness greater than the thickness of sacrificial layers 104. In some embodiments, nanosheet channel layers 106 can be formed of a thickness ranging from about 10 nm to about 18 nm.

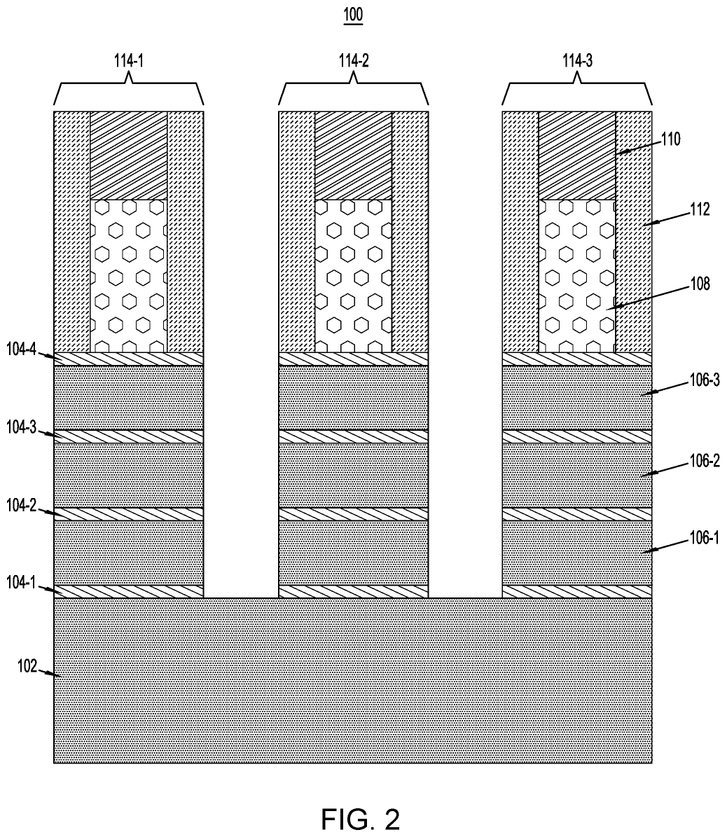

Referring now to FIG. 2, semiconductor structure 100 is shown following nanosheet patterning and formation of nanosheet devices 114-1 to 114-3 together with dummy gates 108, a hardmask layer 110 and sidewall spacers 112 according to an embodiment of the invention. Each of the nanosheet devices 114-1 to 114-3 contain a respective nanosheet transistor. However, this is merely illustrative and it is contemplated that nanosheet devices 114-1 to 114-3 can contain any number of FET devices. Nanosheet devices 114-1 to 114-3 may include nFET devices and/or pFET devices.

Dummy gates 108 and a hardmask layer 110 are first deposited on the topmost sacrificial layer 104-4 by conventional deposition techniques such as ALD, CVD, PVD, etc. Suitable dummy gate material includes, for example, polycrystalline silicon, amorphous silicon or microcrystal silicon. Hardmask layer 110 can be composed of a flowable organic material such as, for example, a spin-on-carbon (SOC), Si₃N₄, SiBCN, SiNC, SiN, SiCO, SiO₂, and SiNOC.

Sidewall spacers 112 are then formed on dummy gates 108 and hardmask layer 110 by conventional deposition techniques such as ALD, CVD, PVD, etc. Sidewall spacers 112 may be formed of any suitable insulator, such as SiN, SiBCN, SiCO, SiO₂ and silicon oxycarbonitride (SiOCN). In some exemplary embodiments, sidewall spacers 112 can include a material that is resistant to some etching processes such as, for example, HF chemical etching or chemical oxide removal etching.

Nanosheet devices 114-1 to 114-3 are formed by etching exposed portions of nanosheet channel layers 106 and sacrificial layers 104 to expose substrate 102.

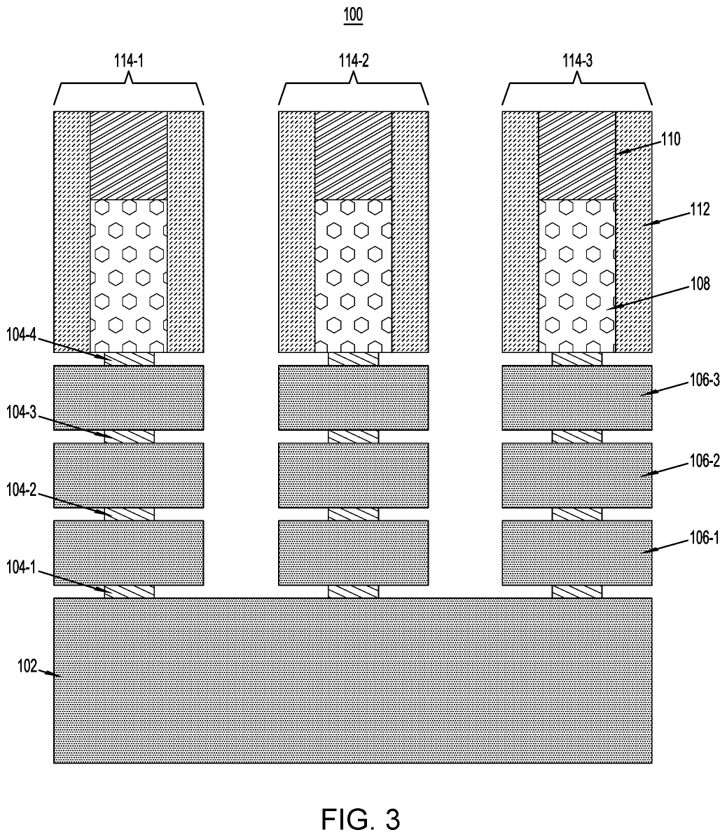

Referring now to FIG. 3, semiconductor structure 100 is shown following the selective removal of a portion of sacrificial layers 104 from each of the nanosheet devices 114-1 to 114-3 according to an embodiment of the invention. The indent spaces may be formed by the selective indent etches of sacrificial layers 104 using, for example, a suitable wet or dry etch.

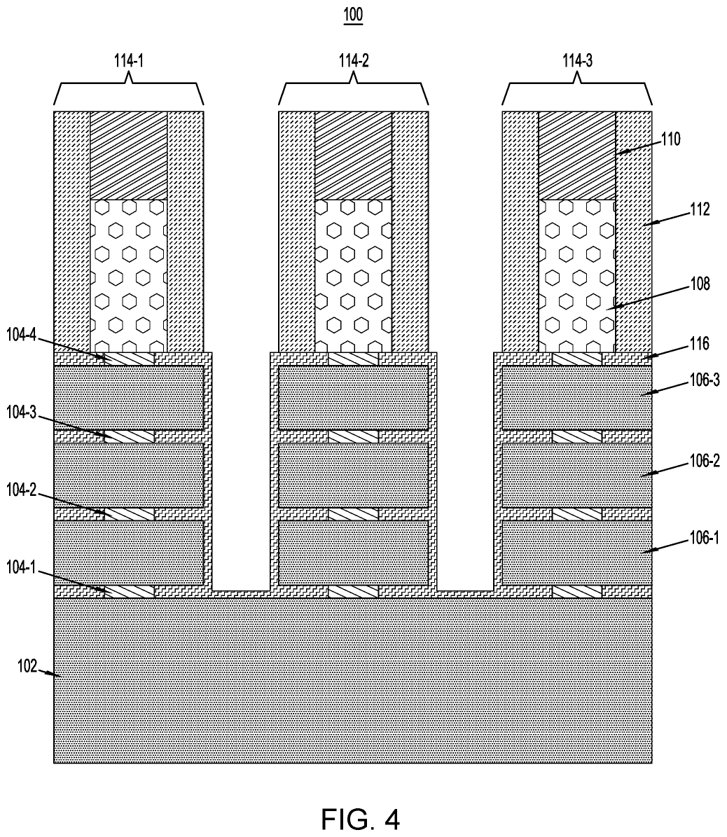

Referring now to FIG. 4, semiconductor structure 100 is shown following the deposition of a sacrificial layer 116 according to an embodiment of the invention. Sacrificial layer 116 is deposited in the indent spaces of each of the nanosheet devices 114-1 to 114-3, along the sidewalls of nanosheet channel layers 106 and on the top surface of the exposed portion of substrate 102 using standard SiGe epitaxial growth processing. Sacrificial layer 116 is formed of SiGe. In some embodiments, sacrificial layer 116 has a lower percentage of Ge than sacrificial layers 104. For example, sacrificial layers 104 may have a relatively higher percentage of Ge (e.g., 55% Ge), while sacrificial layer 116 has a relatively lower percentage of Ge (e.g., 25% Ge).

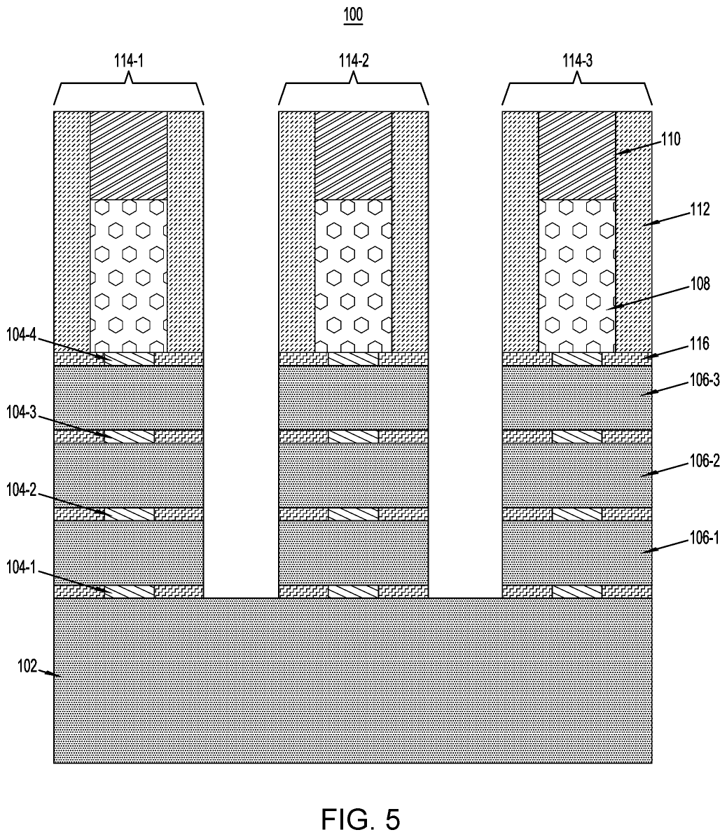

Referring now to FIG. 5, semiconductor structure 100 is shown following the selective removal of sacrificial layer 116 according to an embodiment of the invention. Sacrificial layer 116 is removed from the sidewalls of nanosheet channel layers 106 on nanosheet devices 114-1 to 114-3 and the top surface of the exposed portion of substrate 102 using, for example, isotropic etch-back processing.

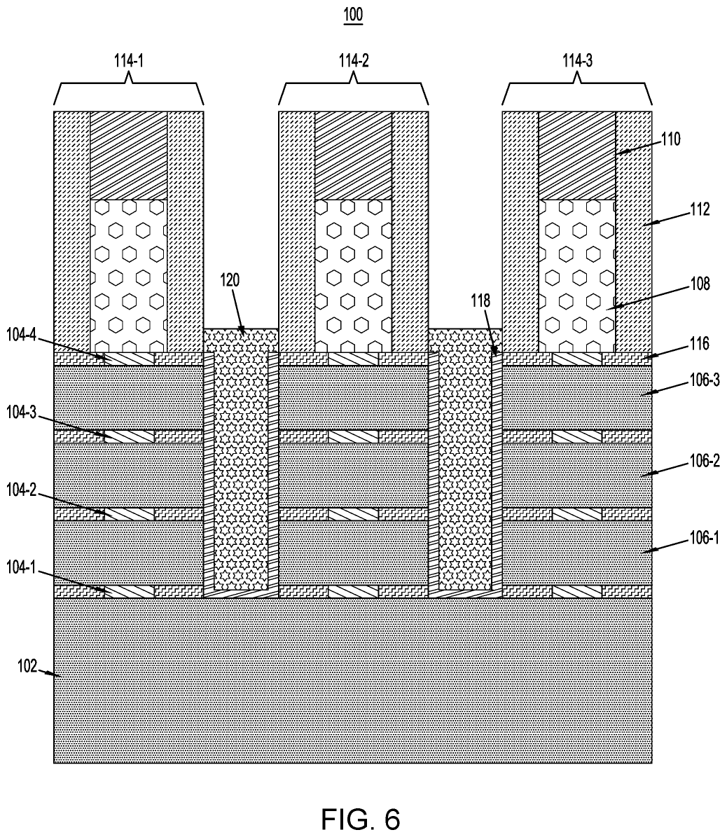

Referring now to FIG. 6, semiconductor structure 100 is shown following the formation of a source/drain liner layer 118 and source/drain source/drain regions 120 between opposing sidewalls of source/drain liner layer 118 between adjacent nanosheet devices 114-1 to 114-3 according to an embodiment of the invention. In some embodiments, source/drain liner layer 118 can be formed, for example, in an epitaxial deposition chamber, where source/drain liner layer 118 may be formed in situ on the sidewalls of nanosheet channel layers 106 and the top surface of the exposed portion of substrate 102. In some embodiments, source/drain liner layer 118 can be a pFET liner layer 118 and source/drain regions 120 cam be pFET source/drain regions 120. In some embodiments, pFET liner layer 118 may be formed of, for example, Si:B (boron doped Si). Next, the chemistry of the deposition chamber can be switched in situ to SiGe:B (boron doped SiGe), for example, to grow the pFET source/drain regions 120 on pFET liner layer 118 and on a portion of sidewall spacers 112. In some embodiments, pFET liner layer 118 includes silicon and pFET source/drain regions 120 include SiGe.

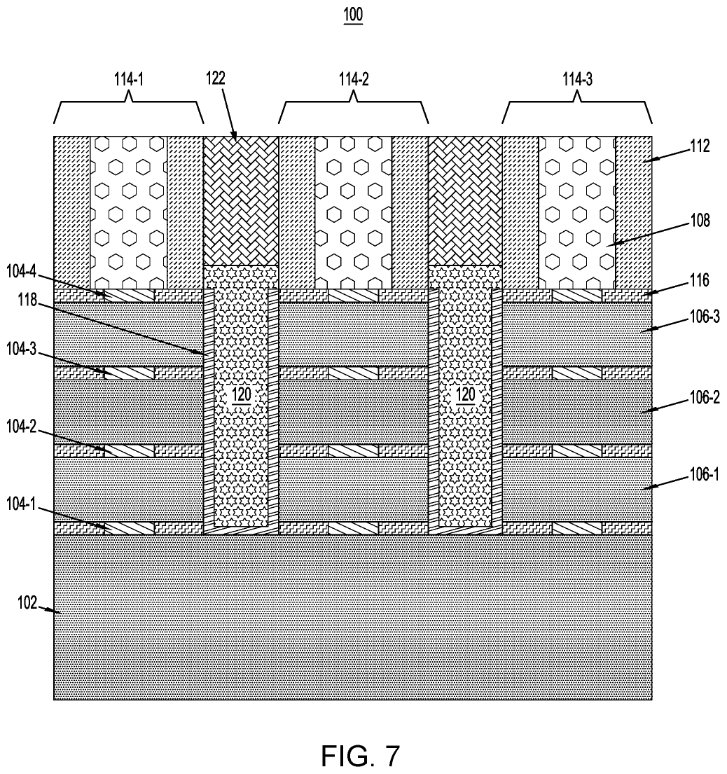

Referring now to FIG. 7, semiconductor structure 100 is shown following the formation of an interlayer dielectric (ILD) layer 122 according to an embodiment of the invention. ILD layer 122 is formed on source/drain regions 120 between adjacent nanosheet devices 114-1 to 114-3, followed by a planarization process such as CMP to also remove hardmask layer 110 and a portion of sidewall spacers 112. ILD layer 122 can be formed of any suitable dielectric material, such as SiO2, SiOC, SiON, etc.

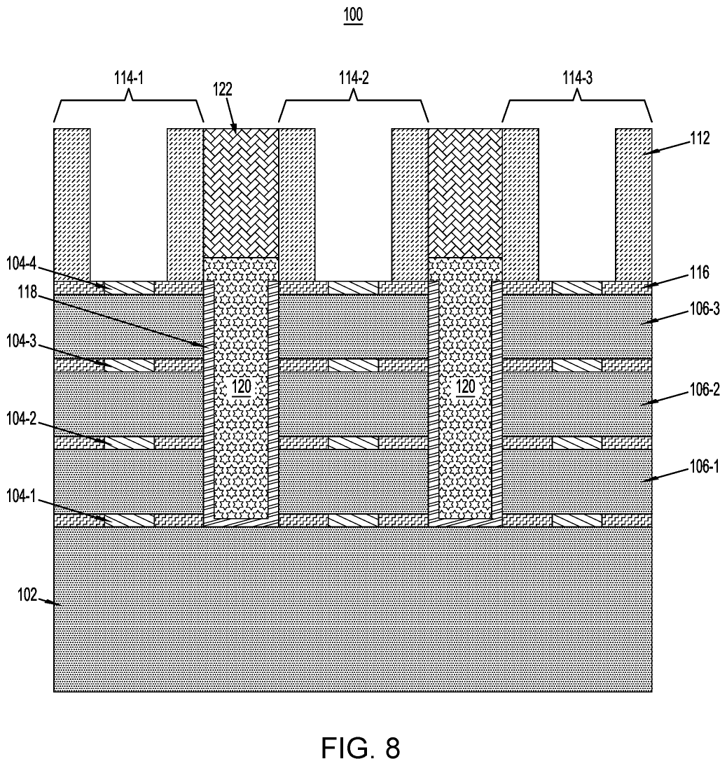

Referring now to FIG. 8, semiconductor structure 100 is shown following the removal of dummy gates 108 from each of the nanosheet devices 114-1 to 114-3 according to an embodiment of the invention. Dummy gates 108 are removed using one or more wet or dry etching processes to thereby define a gate cavity where a replacement gate structure will subsequently be formed for the semiconductor structure 100.

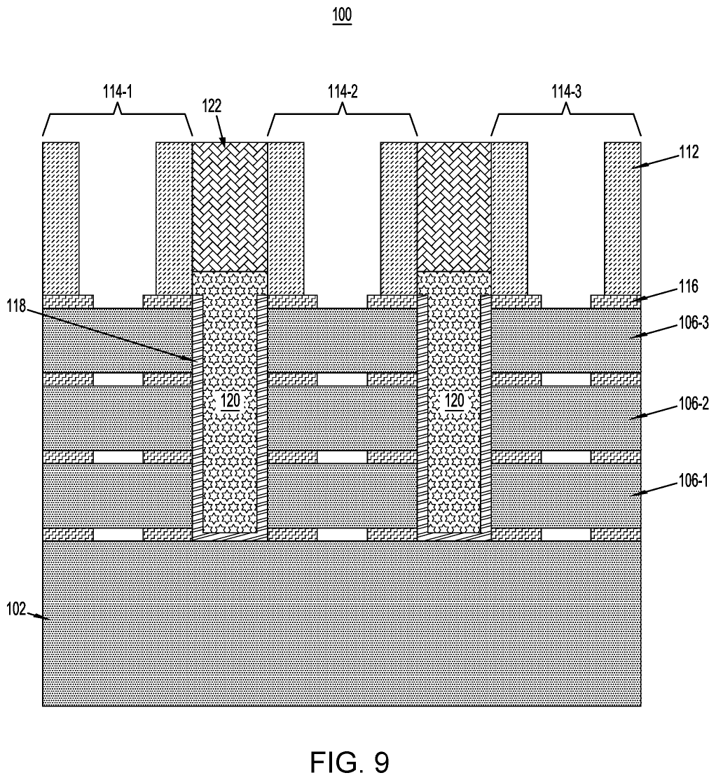

Referring now to FIG. 9, semiconductor structure 100 is shown following the removal of sacrificial layers 104 from each of the nanosheet devices 114-1 to 114-3 according to an embodiment of the invention. Sacrificial layers 104 are selectively removed relative to the other layers including sacrificial layer 116 using one or more wet or dry etching processes to expose a portion of nanosheet channel layers 106.

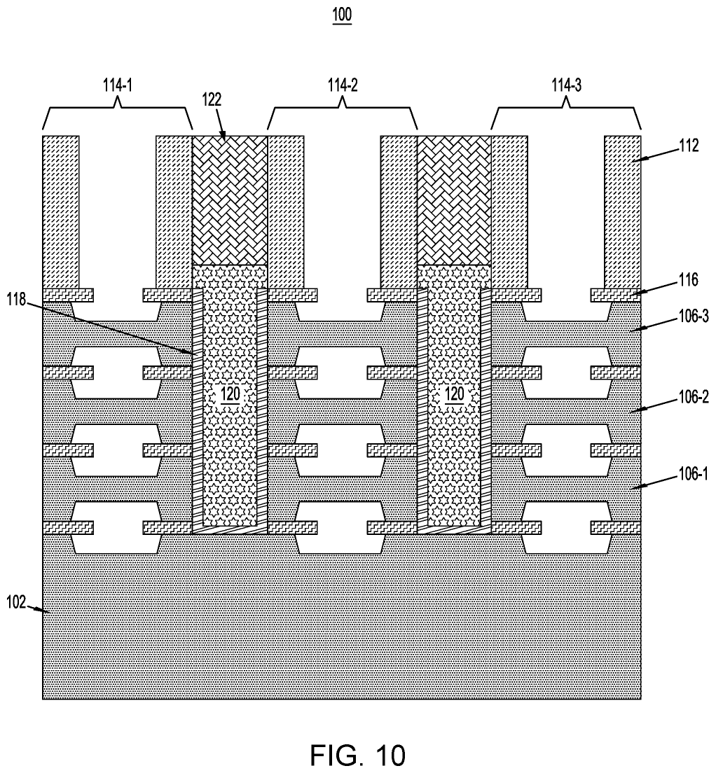

Referring now to FIG. 10, semiconductor structure 100 is shown following the removal of a portion of nanosheet channel layers 106 from each of the nanosheet devices 114-1 to 114-3 according to an embodiment of the invention. The exposed portions of nanosheet channel layers 106 are trimmed to a desired thickness using a suitable chemical etching process such as, for example, a selective Si wet etch or dry etch process.

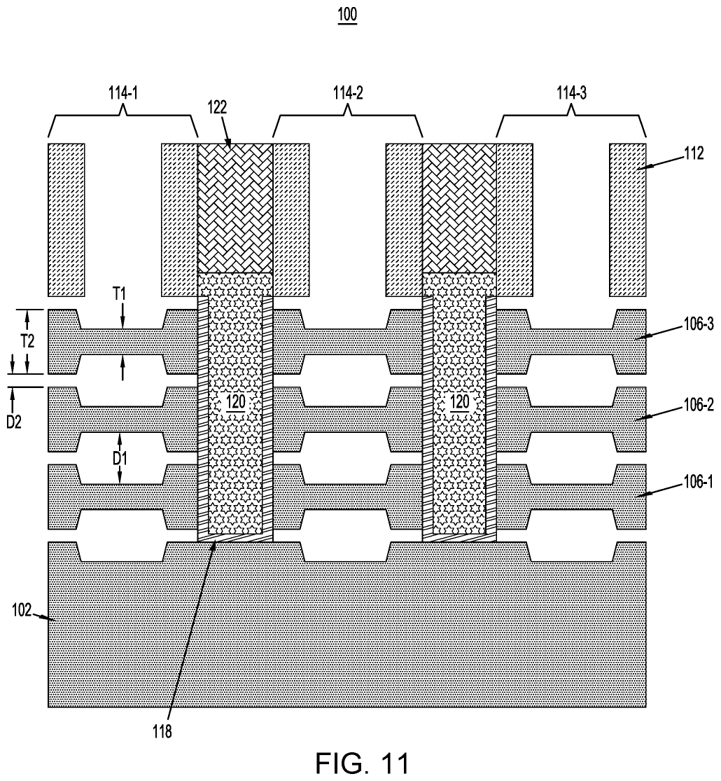

Referring now to FIG. 11, semiconductor structure 100 is shown following the removal of sacrificial layer 116 from each of the nanosheet devices 114-1 to 114-3 according to an embodiment of the invention. Sacrificial layer 116 is selectively removed using one or more wet or dry etching processes.

Following the removal of sacrificial layer 116, each of the nanosheet channel layers 106 in each of the nanosheet devices 114-1 to 114-3 will have a middle portion having a thickness T1 and outer portions having a thickness T2 greater than the thickness of T1. By forming nanosheet channel layers 106 each having a middle portion with thickness T1 and outer portions with thickness T2, a first distance D1 between adjacent middle portions of each of the nanosheet channel layers 106 defines a first region and a second distance D2 between adjacent outer portions of each of the nanosheet channel layers 106 defines a second region, wherein the second distance D2 is less than the first distance D1 in each of the nanosheet devices 114-1 to 114-3.

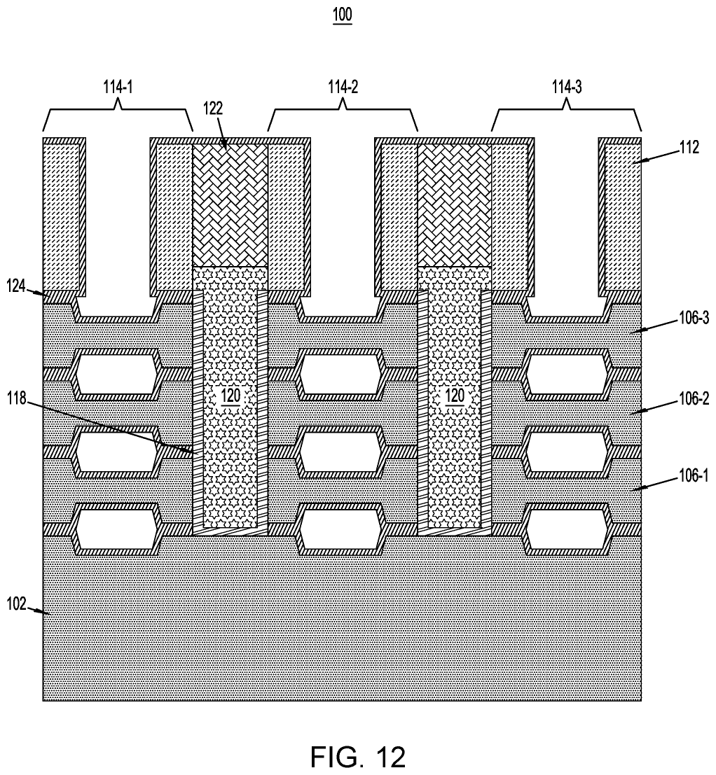

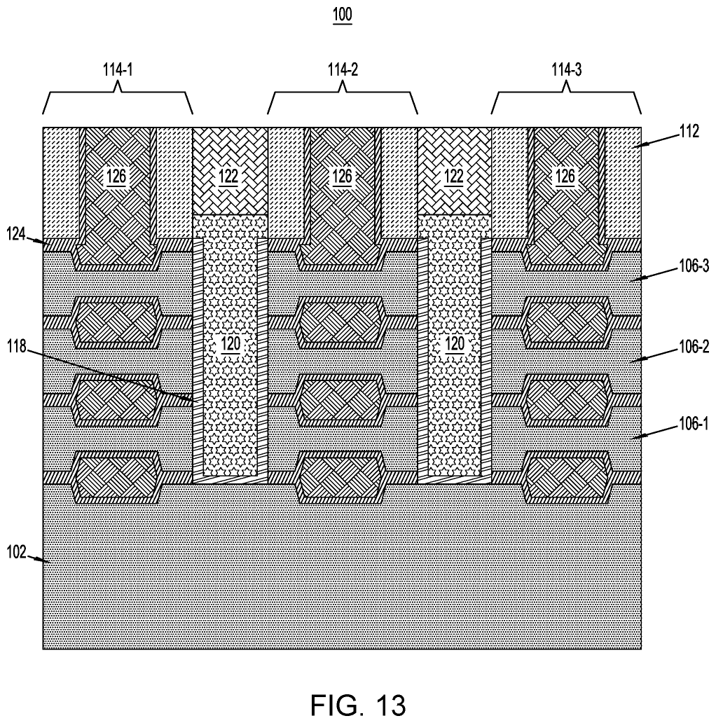

Referring now to FIG. 12, semiconductor structure 100 is shown following the formation of a gate dielectric layer 124 in each of the nanosheet devices 114-1 to 114-3 according to an embodiment of the invention. Gate dielectric layer 124 may be formed on the exposed surfaces of nanosheet channel layers 106 and sidewall spacers 112 using conventional deposition techniques such as ALD, CVD, PVD, etc. In some embodiments, gate dielectric layer 124 is deposited in the first region between adjacent middle portions of each of the nanosheet channel layers 106 and in the second region between adjacent outer portions of each of the nanosheet channel layers 106 to pinch off the second region in each of the nanosheet devices 114-1 to 114-3. For purposes of this disclosure, the term “pinch off” refers to where the second region between adjacent outer portions of each of the nanosheet channel layers 106 are fully filled with gate dielectric layer 124 and have an absence of a conductive gate layer 126 as discussed below with reference to FIG. 13. In addition, gate dielectric layer 124 is a continuous layer in the first region and the second region.

In some embodiments, gate dielectric layer 124 may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg).

Referring now to FIG. 13, semiconductor structure 100 is shown following the formation of conductive gate layer 126 in each of the nanosheet devices 114-1 to 114-3 according to an embodiment of the invention. Conductive gate layer 126 may be formed on the exposed surfaces of gate dielectric layer 124 using conventional deposition techniques such as ALD, CVD, PVD, electroplating. etc. In some embodiments, conductive gate layer 126 includes work function metals, such as TiN, TiC, TiAl, TiAlC, etc., and conductive metal fills such as W, Al, or Ru. FIG. 13 shows that conductive gate layer 126 fills the first region between adjacent middle portions of each of the nanosheet channel layers 106, and that gate dielectric layer 124 is disposed in the second region between adjacent outer portions of each of the nanosheet channel layers 106 and fills the second region. FIG. 13 further shows that source/drain region 120 is separated from conductive gate layer 126 by source/drain liner layer 118 and gate dielectric layer 124 in each of the nanosheet devices 114-1 to 114-3.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first nanosheet channel layer having a first middle portion and first outer portions;
a second nanosheet channel layer disposed over the first nanosheet channel layer, the second nanosheet channel layer having a second middle portion and second outer portions, wherein a first distance between the first middle portion and the second middle portion defines a first region and a second distance between the first outer portions and the second outer portions defines a second region, wherein the second distance is less than the first distance;
a gate dielectric layer disposed in the first region and the second region, wherein the gate dielectric layer pinches off the second region; and
a conductive gate layer disposed on the gate dielectric layer disposed in the first region.

2. The semiconductor structure according to claim 1, wherein the gate dielectric layer fills the second region.

3. The semiconductor structure according to claim 1, wherein the gate dielectric layer is a continuous layer in the first region and the second region.

4. The semiconductor structure according to claim 1, wherein the conductive gate layer fills the first region.

5. The semiconductor structure according to claim 1, further comprising a source/drain liner layer disposed on sidewalls of the first nanosheet channel layer, the second nanosheet channel layer and the gate dielectric layer disposed in the second region, and a source/drain region disposed on the source/drain liner layer.

6. The semiconductor structure according to claim 5, wherein the source/drain region is separated from the conductive gate layer by the source/drain liner layer and the gate dielectric layer disposed in the second region.

7. The semiconductor structure according to claim 5, wherein the source/drain liner layer comprises silicon and the source/drain region comprises SiGe.

8. The semiconductor structure according to claim 7, wherein the source/drain liner layer is a pFET source/drain liner layer and the source/drain region is a pFET source/drain region.

9. A semiconductor structure, comprising:
a first nanosheet device disposed on a substrate comprising a plurality of first nanosheet channel layers, wherein each of the plurality of first nanosheet channel layers has a first middle portion and first outer portions, wherein a first distance between the first middle portion of adjacent first nanosheet channel layers defines a first region and a second distance between the first outer portions of adjacent first nanosheet channel layers defines a second region, wherein the second distance is less than the first distance;
a second nanosheet device adjacent the first nanosheet device, the second nanosheet device comprising a plurality of second nanosheet channel layers, wherein each of the plurality of second nanosheet channel layers has a second middle portion and second outer portions, wherein a third distance between the second middle portion of adjacent second nanosheet channel layers defines a third region and a fourth distance between the second outer portions of adjacent second nanosheet channel layers defines a fourth region, wherein the fourth distance is less than the third distance;
a first gate dielectric layer disposed in the first region and the second region, wherein the first gate dielectric layer pinches off the second region;
a second gate dielectric layer disposed in the third region and the fourth region, wherein the second gate dielectric layer pinches off the fourth region;
a first conductive gate layer disposed on the first gate dielectric layer disposed in the first region; and
a second conductive gate layer disposed on the second gate dielectric layer disposed in the third region.

10. The semiconductor structure according to claim 9, wherein the first gate dielectric layer fills the second region and the second gate dielectric layer fills the fourth region.

11. The semiconductor structure according to claim 9, wherein the first gate dielectric layer disposed in the first region and the second region is a first continuous layer, and the second gate dielectric layer disposed in the third region and the fourth region is a second continuous layer.

12. The semiconductor structure according to claim 10, wherein the first conductive gate layer fills the first region and the second conductive gate layer fills the third region.

13. The semiconductor structure according to claim 10, further comprising:
a first source/drain liner layer disposed on sidewalls of the plurality of first nanosheet channel layers and the first gate dielectric layer of the first nanosheet device;
a second source/drain liner layer disposed on sidewalls of the plurality of second nanosheet channel layers and the second gate dielectric layer of the second nanosheet device; and
a source/drain region disposed between opposing sidewalls of the first source/drain liner layer and the second source/drain liner layer.

14. The semiconductor structure according to claim 13, wherein the source/drain region is separated from the first conductive gate layer by the first source/drain liner layer and the first gate dielectric layer, and from the second conductive gate layer by the second source/drain liner layer and the second gate dielectric layer.

15. The semiconductor structure according to claim 13, wherein the first source/drain liner layer and the second source/drain liner layer each comprise silicon and the source/drain region comprises SiGe.

16. The semiconductor structure according to claim 15, wherein the first source/drain liner layer and the second source/drain liner layer are each a pFET source/drain liner layer and the source/drain region is a pFET source/drain region.

17. An integrated circuit, comprising:
one or more semiconductor structures, wherein at least one of the one or more semiconductor structures comprises:
a first nanosheet channel layer having a first middle portion and first outer portions;
a second nanosheet channel layer disposed over the first nanosheet channel layer, the second nanosheet channel layer having a second middle portion and second outer portions, wherein a first distance between the first middle portion and the second middle portion defines a first region and a second distance between the first outer portions and the second outer portions defines a second region, wherein the second distance is less than the first distance;
a gate dielectric layer disposed in the first region and the second region, wherein the gate dielectric layer pinches off the second region; and
a conductive gate layer disposed on the gate dielectric layer disposed in the first region.

18. The integrated circuit according to claim 17, wherein the conductive gate layer fills the first region, and wherein the gate dielectric layer fills the second region.

19. The integrated circuit according to claim 17, further comprising a source/drain liner layer disposed on sidewalls of the first nanosheet channel layer, the second nanosheet channel layer and the gate dielectric layer disposed in the second region, and a source/drain region disposed on the source/drain liner layer.

20. The integrated circuit according to claim 19, wherein the source/drain liner layer comprises silicon and the source/drain region comprises SiGe.
